(19) United States
(12) Patent Application Publication
(10) Pub. No.: US 2023/0118976 A1
(43) Pub. Date: Apr. 20, 2023

(54) SEMICONDUCTOR DEVICE AND METHOD OF FABRICATING THE SAME

(71) Applicant: MACRONIX INTERNATIONAL CO., LTD., Hsinchu (TW)

(72) Inventors: Mao-Yuan WENG, Hualien City (TW); Ting-Feng LIAO, Hsin-chu (TW); Kuang-Wen LIU, Hsin-chu (TW)

(21) Appl. No.: 17/500,977

(22) Filed: Oct. 14, 2021

(51) Int. Cl. H01L 27/11526; H01L 27/11556; H01L 27/11573; H01L 27/11582

(52) U.S. Cl. CPC H01L 27/11526; H01L 27/11556; H01L 27/11573; H01L 27/11582

(57) ABSTRACT

A semiconductor device includes a peripheral circuit region, a substrate on the peripheral circuit region, and an array region on the substrate. The peripheral circuit region includes a plurality of complementary metal-oxide-semiconductor components. The substrate includes an N-type doped poly silicon layer on the peripheral circuit region, an insulating layer on the N-type doped poly silicon layer; and a P-type doped poly silicon layer on the insulating layer. The array region includes a plurality of gate structures and a plurality of oxide layers alternately stacked on the P-type doped poly silicon layer, wherein a bottommost gate structure of the gate structures and the P-type doped poly silicon layer together serve as a plurality ground select lines of the semiconductor device. The array region further includes a vertical channel structure penetrating the gate structures and the oxide layers and extending into the N-type doped poly silicon layer.

### BACKGROUND

### Field of Invention

The present invention relates to a semiconductor device and a method of fabricating the same.

### Description of Related Art

In recent years, the structures of semiconductor devices have been changed constantly, and the storage capacity of the devices has been increased continuously. Memory devices are used in storage elements for many products such as digital cameras, mobile phones, computers, etc. As the application increases, the demand for the memory device focuses on small size and large memory capacity. For satisfying the requirement, a memory device having a high element density and a small size and the manufacturing method thereof are in need.

As such, it is desirable to develop a three-dimensional (3D) memory device with larger number of multiple stacked planes to achieve greater storage capacity, improved qualities, all the while remaining in a small size.

### SUMMARY

According to some embodiments of the disclosure, a semiconductor device includes a peripheral circuit region, a substrate on the peripheral circuit region, and an array region on the substrate. The peripheral circuit region includes a plurality of complementary metal-oxide-semiconductor components. The substrate includes an N-type doped poly silicon layer on the peripheral circuit region, an insulating layer on the N-type doped poly silicon layer; and a P-type doped poly silicon layer on the insulating layer. The array region includes a plurality of gate structures and a plurality of oxide layers alternately stacked on the P-type doped poly silicon layer, wherein a bottommost gate structure of the gate structures and the P-type doped poly silicon layer together serve as a plurality ground select lines of the semiconductor device. The array region further includes a vertical channel structure penetrating the gate structures and the oxide layers and extending into the N-type doped poly silicon layer.

According to some embodiments of the disclosure, a method of fabricating a semiconductor device includes providing a structure. The substrate includes a peripheral circuit region, a substrate on the peripheral circuit region, and an array region on the substrate. The peripheral circuit region includes a plurality of complementary metal-oxide-semiconductor components. The substrate includes a first poly silicon layer on the peripheral circuit region, in which the first poly silicon layer is doped with N-type dopants, a first oxide layer on the first poly silicon layer, a second poly silicon layer on the first oxide layer, a second oxide layer on the second poly silicon layer, a third poly silicon layer on the second oxide layer, a third oxide layer on the third poly silicon layer, and a fourth poly silicon layer on the third oxide layer. The array region includes a plurality of oxide layers and a plurality of nitride layers alternately stacked on the fourth poly silicon layer, and a vertical channel structure penetrating the oxide layers and the nitride layers and extending into the first poly silicon layer. The method further includes replacing the fourth poly silicon layer with a P-type doped poly silicon layer, removing the second poly silicon layer and removing the first oxide layer and the second oxide layer thereby forming a cavity between the third poly silicon layer and the first poly silicon layer, and filling the cavity with an N-type doped poly silicon material, such that an N-type doped poly silicon layer is formed between the third oxide layer and the peripheral circuit region.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 to FIG. 13 are cross-sectional views of sequential steps of a method of forming a semiconductor device, according to some embodiments of the disclosure; and

FIG. 14 is a partial view of area A of the semiconductor structure in FIG. 13.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

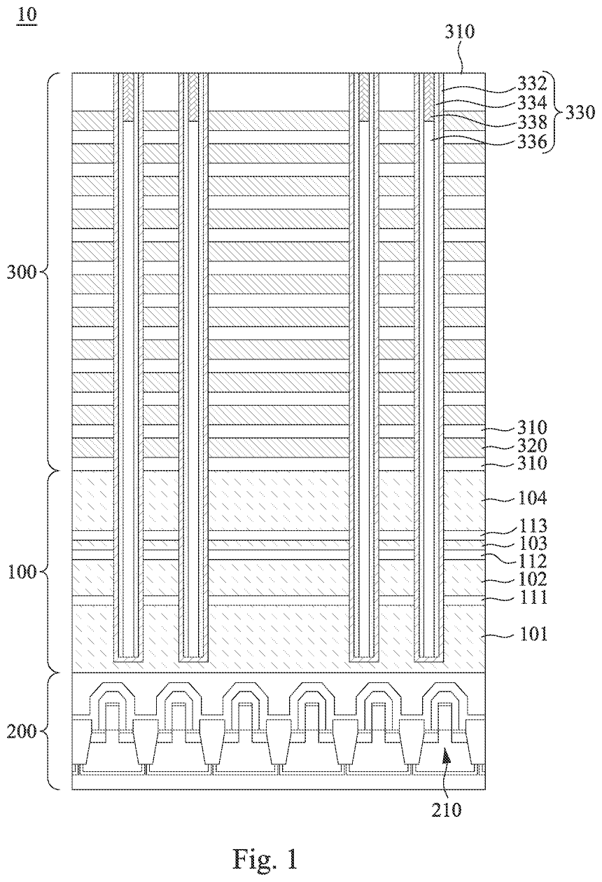

FIG. 1 to FIG. 13 are cross-sectional views of sequential steps of a method of forming a semiconductor device, according to some embodiments of the disclosure. Reference is made to FIG. 1, a semiconductor structure 10 is provided. The semiconductor structure 10 includes a substrate 100, a peripheral circuit region 200 disposed below the substrate 100, and an array region 300 disposed above the substrate 100. Namely, the peripheral circuit region 200 and the array region 300 are disposed on opposite surfaces of the substrate 100, respectively. In some embodiments, the substrate 100 is formed on the top surface of the peripheral circuit region 200, and then the array region 300 is then formed on the top surface of the substrate 100. In some other embodiments, the array region 300 is formed on the top surface of the substrate 100, and the substrate 100 and the array region 300 thereon are bonded on the peripheral circuit region 200.

The peripheral circuit region 200 includes a plurality of semiconductor components, such as a plurality of complementary metal-oxide-semiconductor (CMOS) components 210 and other suitable circuits.

The substrate 100 is, for example, a silicon substrate. The substrate 100 includes a first poly silicon layer 101 on the peripheral circuit region 200, a first oxide layer 111 on the first poly silicon layer 101, a second poly silicon layer 102 on the first oxide layer 111, a second oxide layer 112 on the second poly silicon layer 102, a third poly silicon layer 103 on the second oxide layer 112, a third oxide layer 113 on the third poly silicon layer 103, and a fourth poly silicon layer 104 on the third oxide layer 113.

In some embodiments, the first poly silicon layer 101 has a largest thickness among the poly silicon layers 101-104 of the substrate 100, and the third poly silicon layer 103 has a smallest thickness among the poly silicon layers 101-104 of the substrate 100. In some embodiments, the thickness of the first poly silicon layer 101 is about 1500 Å, the thickness of the second poly silicon layer 102 is about 400 Å, the thickness of the third poly silicon layer 103 is about 100 Å, and the thickness of the fourth poly silicon layer 101 is about 1000 Å. In some embodiments, the thickness of the first oxide layer 111 is about 80 Å, the thickness of the second oxide layer 112 is about 120 Å, and the thickness of the third oxide layer 113 is about 450 Å.

The first poly silicon layer 101 is doped with N-type dopants such as, for example, phosphorus (P) and arsenic (As), and the fourth poly silicon layer 104 is doped with P-type dopants such as, for example, boron (B) and gallium (Ga). In some embodiments, the fourth poly silicon layer 104 serves as ground select line (GSL) of the semiconductor device.

The array region 300 includes a plurality of first insulating layers 310 and second insulating layers 320 alternately stacked on the substrate 100, in which both the topmost layer and the bottom most layer are the first insulating layers 310, and a material of the first insulating layers 310 is different from a material of the second insulating layers 320. In some embodiments, the first insulating layers 310 are oxide layers such as silicon oxide layers, and the second insulating layers 320 are nitride layers such as silicon nitride layers.

The array region 300 further includes a plurality of vertical channel structures 330 arranged parallel to the normal direction of the substrate 100. The vertical channel structures 330 are formed penetrating the stack of the first insulating layers 310 and the second insulating layers 320 and are further extend into the substrate 100. In some embodiments, the vertical channel structures 330 stop at the first poly silicon layer 101.

In some embodiments, each of the vertical channel structures 330 includes a storage layer 332, a channel layer 334, and an isolation pillar 336. The channel layer 334 is sandwiched between the storage layer 332 and the isolation pillar 336. The storage layer 332 and the channel layer 334 have U-shaped cross-sections. In some embodiments, the storage layer 332 is a multi-layer structure, such as an oxide-nitride-oxide (ONO) layer that is able to trap electrons. The channel layer 334 may be made of a material including poly silicon, and the isolation pillar 336 may be made of dielectric material. Each of the vertical channel structures 330 further includes a conductive plug 338 disposed on the isolation pillar 336 and in contact with the channel layer 334. In some embodiments, the top surfaces of the conductive plug 338, the storage layer 332, the channel layer 334, and the topmost silicon oxide layer 310 are substantially coplanar. The top surface of the isolation pillar 336 is below the top surface of the channel layer 334, and the sidewall of the conductive plug 338 is in contact with the channel layer 334.

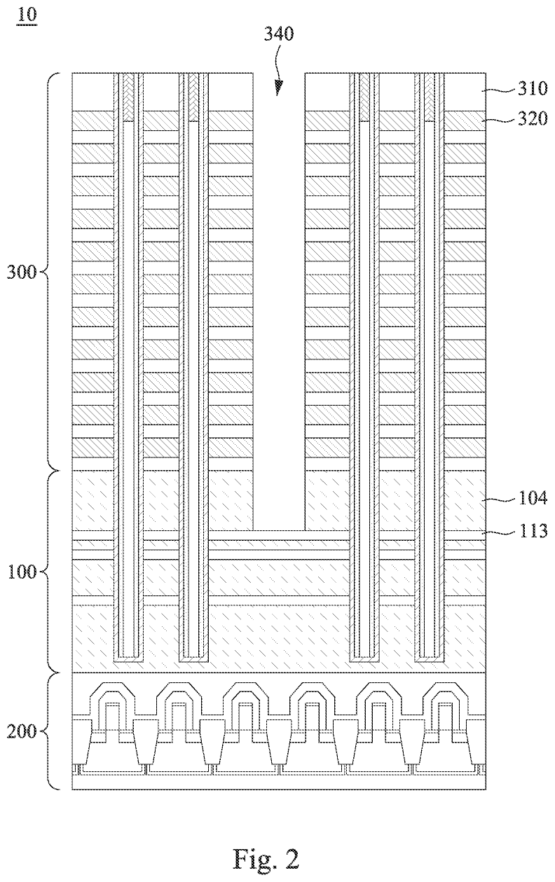

Reference is made to FIG. 2. One or more etching processes are performed to form a trench 340 in the array region 300. For example, a first etching process is performed to remove portions of the first insulating layers 310, the second insulating layers 320, and the fourth poly silicon layer 104. Namely, the trench 340 is formed stopping at the fourth poly silicon layer 104 after the first etching process. Then, a second etching process is performed to deepen the trench 340 such that the trench 340 stops at the third oxide layer 113. Namely, the third oxide layer 113 serves as the etch stop layer of the second etching process. In some embodiments, the first etching process is different from the second etching process.

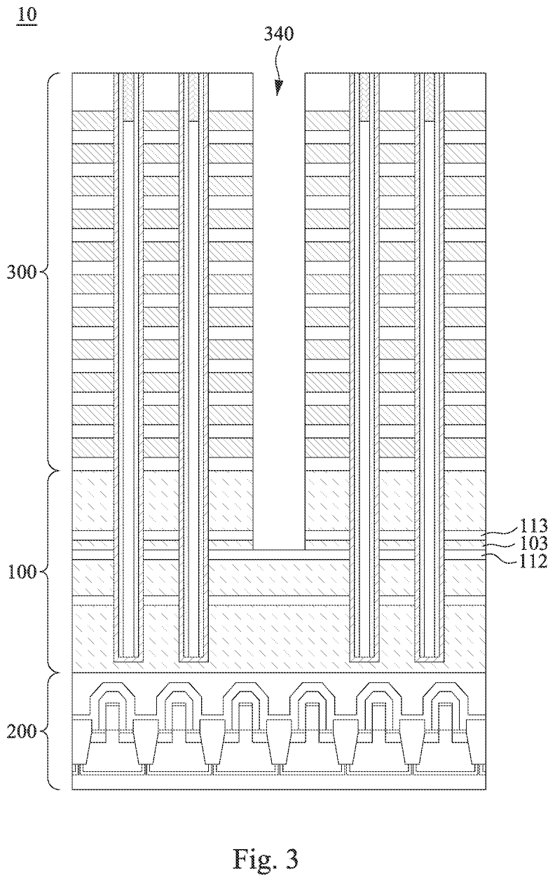

Reference is made to FIG. 3. A third etching process is performed to further deepen the trench 340. The third etching process removes portions of the third oxide layer 113 and the third poly silicon layer 103 and stops at the second oxide layer 112. Namely, the second oxide layer 112 serves as the etch stop layer of the third etching process.

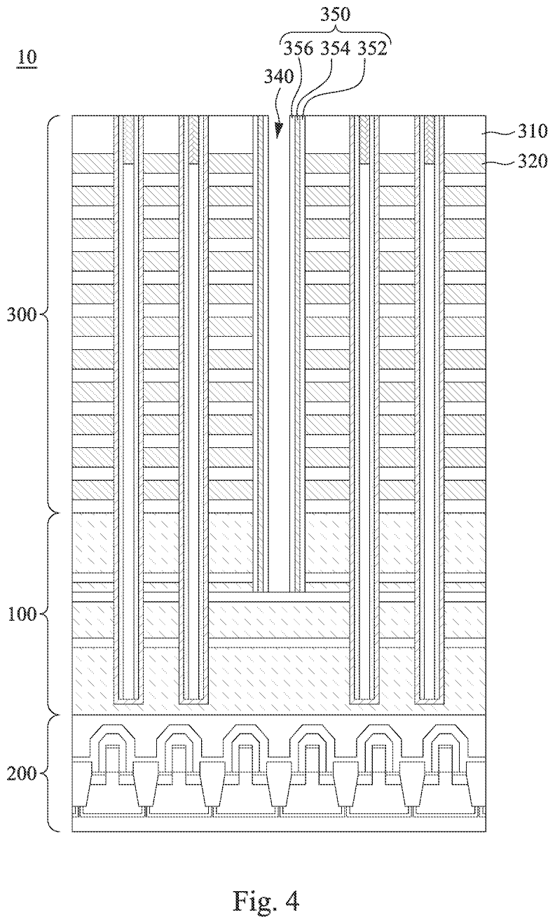

Reference is made to FIG. 4. A spacer 350 is formed on the sidewall of the trench 340. In some embodiments, a spacer material is formed on the top and side surfaces of the semiconductor structure 10 as shown in FIG. 3. Then an etching process is performed to remove the portion of the spacer material on the top surface of the semiconductor structure 10. The portion of the spacer material on the side surface of the semiconductor structure 10 is remained after the etching process, thereby forming the spacer 350 on the sidewall of the trench 340.

In some embodiments, the spacer 350 is a multi-layer structure, which includes a first nitride layer 352, an oxide layer 354, and a second nitride layer 356, in which the first nitride layer 352 is formed on the sidewall of the trench 340, and the oxide layer 354 is sandwiched between the first nitride layer 352 and the second nitride layer 356. The top surface of the first insulating layers 310 and the second insulating layers 320 is protected by a mask after the spacer 350 is formed.

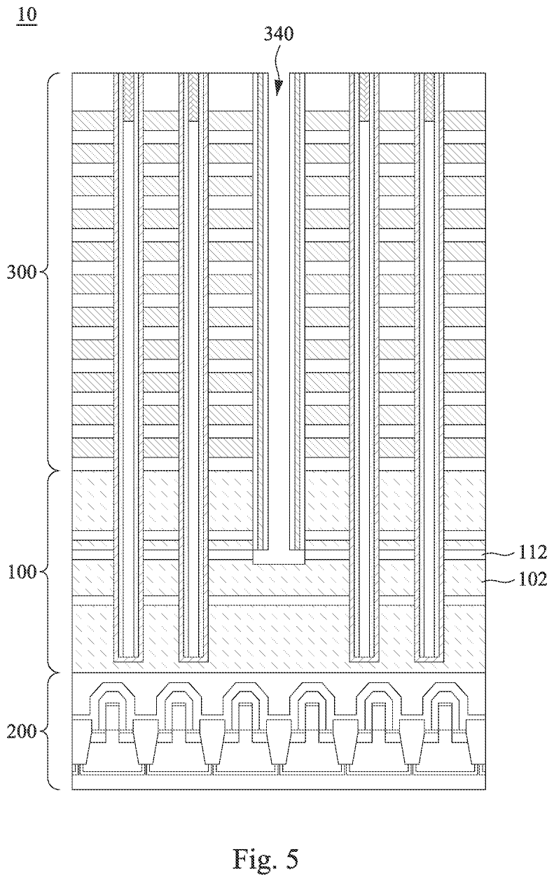

Reference is made to FIG. 5. An etching process is performed to remove portions of the second oxide layer 112 and the second poly silicon layer 102. The etching process stops at the second poly silicon layer 102 thus the sidewall of the second poly silicon layer 102 is exposed from the trench 340.

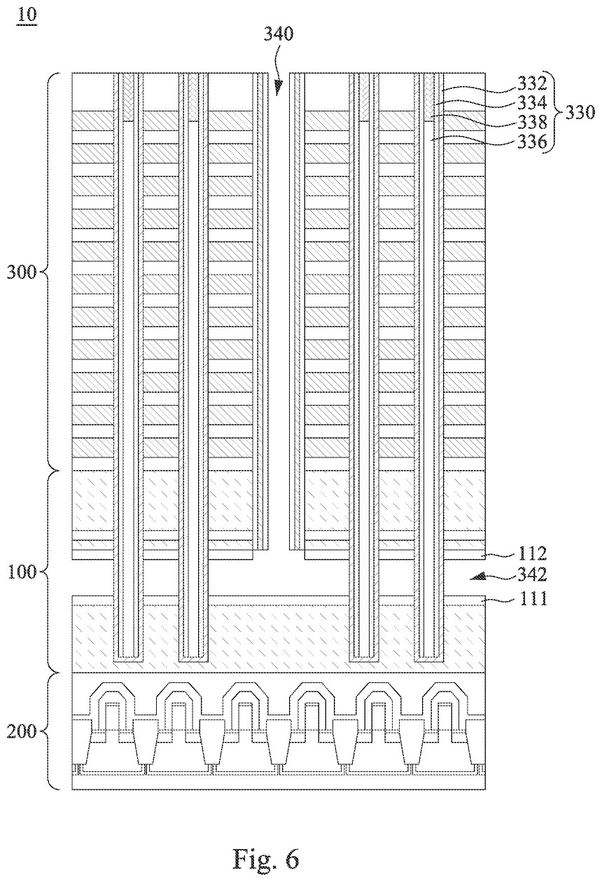

Reference is made to FIG. 6. The second poly silicon layer 102 (see FIG. 5) is removed by using a wet etching. The second poly silicon layer 102 can be also regarded as a sacrificial layer. After the second poly silicon layer 102 is removed, a cavity 342 is formed between the first oxide layer 111 and the second oxide layer 112. Portions of the vertical channel structures 330 between the first oxide layer 111 and the second oxide layer 112 are exposed from the cavity 342.

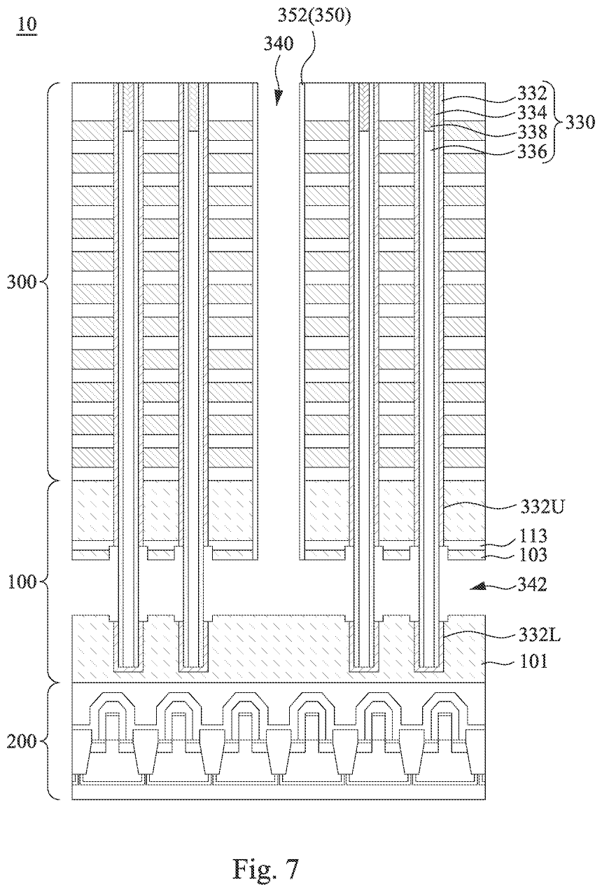

Reference is made to FIG. 7. Sequential etching processes are performed to remove portions of the storage layer 332 of the exposed portions of the vertical channel structures 330. For example, a first etchant that etches oxide faster than nitride and a second etchant that etches nitride faster than oxide are utilized to remove the exposed portion of the storage layer 332, which is the oxide-nitride-oxide layer. During the processes of removing the exposed portions of the storage layer 332 (e.g. the oxide-nitride-oxide layer), the oxide layer 354 and the second nitride layer 356 of the spacer 350 (see FIG. 6), and the first oxide layer 111 and the second oxide layer 112 (see FIG. 6) are also removed accordingly. Therefore, the space of the cavity 342 is enlarged after the removing process. The first nitride layer 352 of the spacer 350 is remained on the sidewall of the trench 340.

In some embodiments, not only the exposed portions of the storage layer 332 are removed, ends of the storage layer 332 covered by the first poly silicon layer 101 and the third poly silicon layer 103 are recessed after removing the exposed portions of the storage layer 332. In some embodiments, the storage layer 332 includes an upper segment 332U and a lower segment 332L, in which the upper segment 332U and the lower segment 332L are spaced apart by the cavity 342.

In some embodiments, the top surface of the lower segment 332L of the storage layer 332 is lower that the topmost surface of the first poly silicon layer 101. In some embodiments, the bottom surface of the upper segment 332U of the storage layer 332 is higher that the bottommost surface of the third poly silicon layer 103 and higher than the bottom surface of the third oxide layer 113. In some embodiments, portions of the third oxide layer 113 adjacent the storage layer 332 are also removed after removing the exposed portions of the storage layer 332.

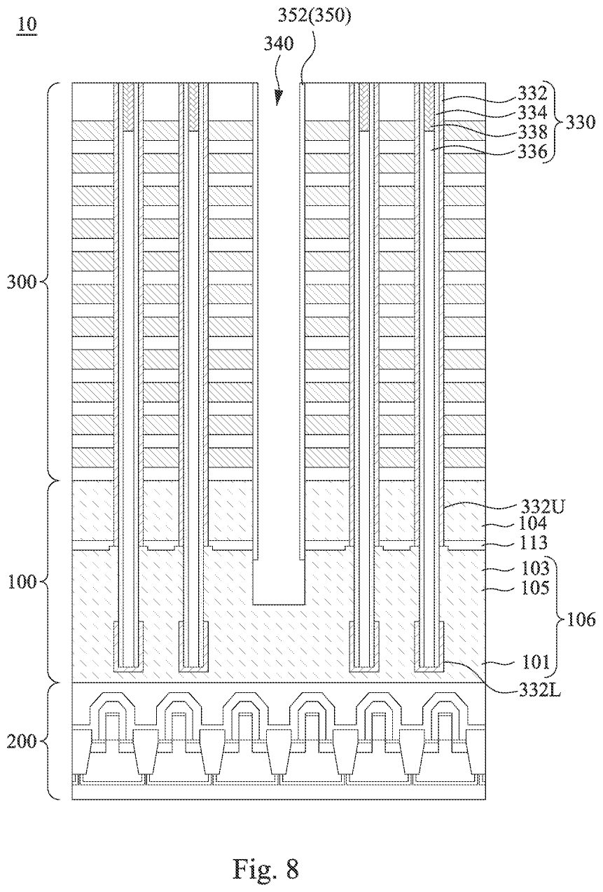

Reference is made to FIG. 8. Additional poly silicon material 105 is epitaxially grown and refilled in the cavity 342 (see FIG. 7). The poly silicon material 105 can be silicon doped with N-type dopants such as, for example, phosphorus (P) and arsenic (As). The combination of the remained third poly silicon layer 103, the poly silicon material 105, and the first poly silicon layer 101 is referred as an N-type doped poly silicon layer 106. The thickness of the N-type doped poly silicon layer 106 is about 2200 Å. The N-type doped poly silicon layer 106 and the fourth poly silicon layer 104 are spaced apart by the third oxide layer 113. That is, the third oxide layer 113 serves as an insulating layer between the N-type doped poly silicon layer 106 and the fourth poly silicon layer 104.

After the N-type doped poly silicon layer 106 is formed, an etch back process is performed to remove a portion of the N-type doped poly silicon layer 106, thereby deepening the trench 340. In some embodiments, the bottom of the trench 340 is between the upper segment 332U and the lower segment 332L of the storage layer 332. The portion of the channel layer 334 between the upper segment 332U and the lower segment 332L of the storage layer 332 is in contact with the N-type doped poly silicon layer 106.

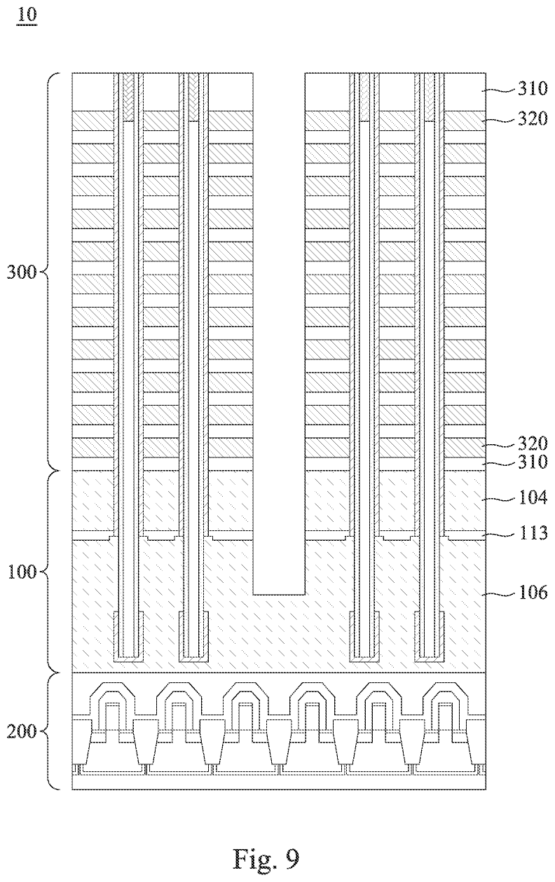

Reference is made to FIG. 9. The first nitride layer 352 of the spacer 350 (see FIG. 8) is removed, such that the sidewalls of the stacked first insulating layers 310 and second insulating layers 320, the fourth poly silicon layer 104, the third oxide layer 113, and the N-type doped poly silicon layer 106 are exposed.

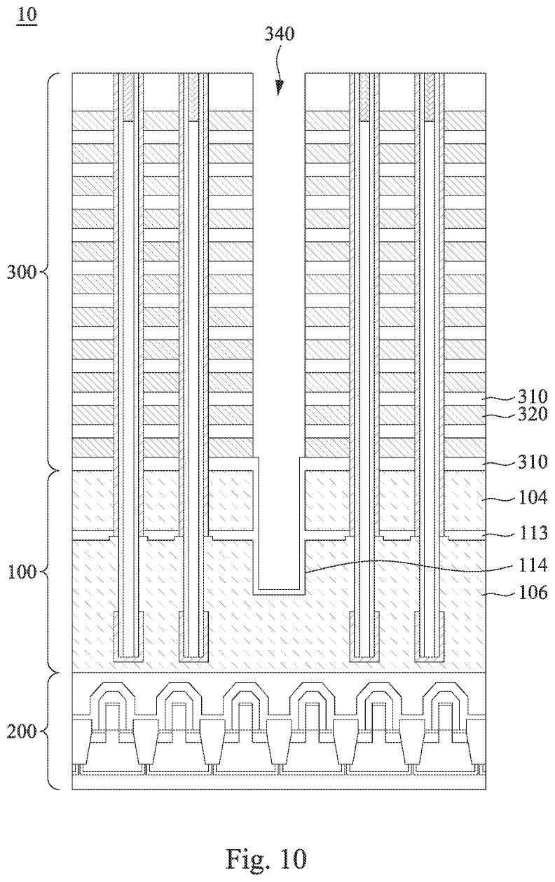

Reference is made to FIG. 10. An oxidation process such as a thermal oxidation process is performed to form a fourth oxide layer 114 on the surface of the fourth poly silicon layer 104 and the N-type doped poly silicon layer 106. The surface of the fourth poly silicon layer 104 and the N-type doped poly silicon layer 106 is transferred to the fourth oxide layer 114 after performing the oxidation process. The sidewalls of the stacked first insulating layers 310 (except the bottommost one) and second insulating layers 320 are free of coverage by the fourth oxide layer 114. In some embodiments, the fourth oxide layer 114 is connected to the bottommost first insulating layers 310 and the third oxide layer 113.

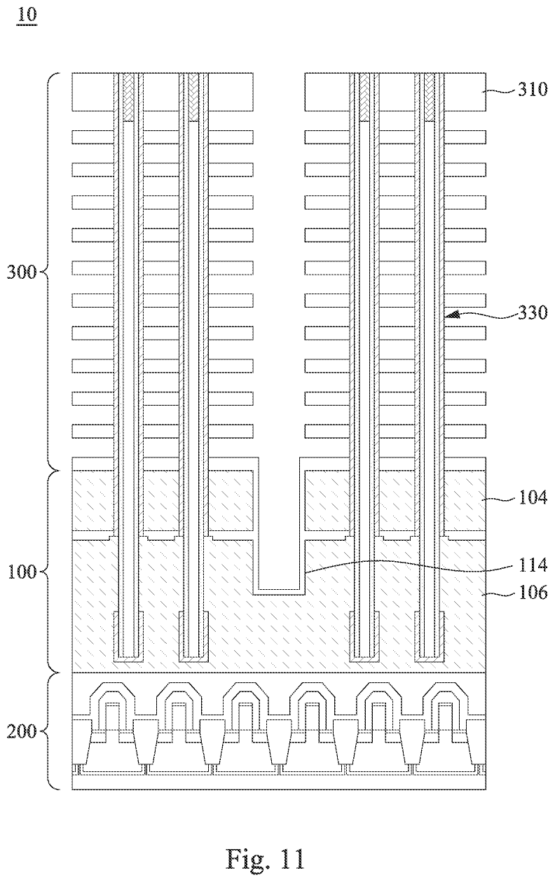

Reference is made to FIG. 11. An etching process is performed to remove the second insulating layers 320 (see FIG. 10). More particularly, the second insulating layers 320 are silicon nitride layers, and the etching process is performed using an etchant that has a greater nitride etching rate than an oxide etching rate such that the first insulating layers 310, which are silicon oxide layers, are remained after the second insulating layers 320 are removed. Portions of the vertical channel structures 330 are exposed between the first insulating layers 310. The fourth oxide layer 114 protects the fourth poly silicon layer 104 and the N-type doped poly silicon layer 106 from being damaged by the etching process.

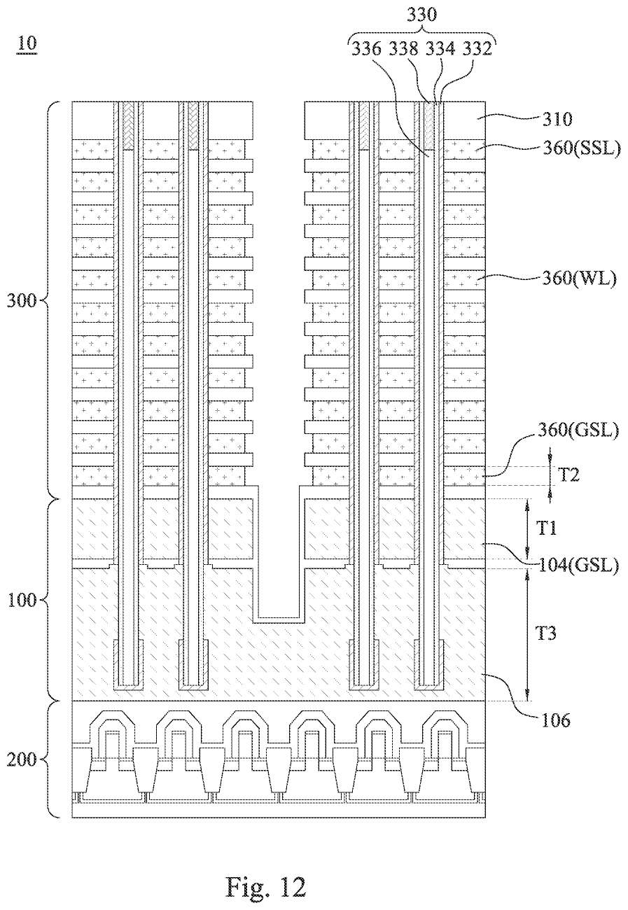

Reference is made to FIG. 12. A plurality of gate structures 360 are formed between the first insulating layers 310 and adjacent the vertical channel structures 330. Each of the gate structures 360 includes one or more gate dielectric layers, one or more work function metal layer, and filling metal such as tungsten (W). In some embodiments, one or more of the gate structures 360 at top of the semiconductor structure 10 serve as string select lines (SSL) of the semiconductor structure 10, one or more of the gate structures 360 at bottom of the semiconductor structure 10 and the P-type doped fourth poly silicon layer 104 together serve as ground select lines (GSL) of the semiconductor structure 10, and the rest of the gate structures 360 serve as word lines (WL) of the semiconductor structure 10. The gate structures 360 surround the vertical channel structures 330, respectively. Therefore, the cells in the array region 300 can be also referred as gate-all-around (GAA) memory cells.

In some embodiments, the thickness T1 of the P-type doped fourth poly silicon layer 104 is greater than the thickness T2 of each of the gate structures 360. In some embodiments, the thickness T1 of the P-type doped fourth poly silicon layer 104 is about 1000 Å, and the thickness T2 of each of the gate structures 360 is about 300 Å. In some embodiments, the ratio of the thickness T1 of the P-type doped fourth poly silicon layer 104 to the thickness T2 of each of the gate structures 360 is about 3 to 4. In some embodiments, the thickness T1 of the P-type doped fourth poly silicon layer 104 is smaller than the thickness T3 of the N-type doped poly silicon layer 106.

After the gate structures 360 are formed, an etch back process is performed to recess the gate structures 360, such that the sidewalls of the gate structures 360 are recessed from the sidewalls of the first insulating layers 310.

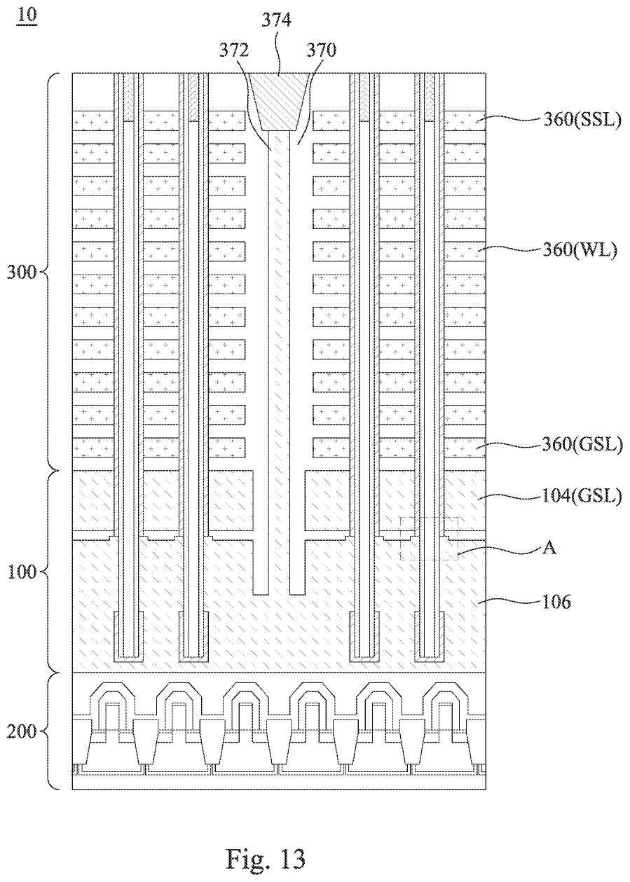

Reference is made to FIG. 13. Additional oxide material is deposited on the sidewalls of the gate structures 360, the first insulating layers 310, and the fourth oxide layer 114 (see FIG. 11). Then an etching process is performed to remove a portion of the oxide material and remove a bottom of the fourth oxide layer 114 to open the fourth oxide layer 114, such that an isolation spacer 370 is formed in the trench 340 (see FIG. 10), and the N-type doped poly silicon layer 106 is revealed from the opened fourth oxide layer 114. An epitaxial growing process is performed to form a common select line (CSL) 372, from the revealed N-type doped poly silicon layer 106, filling the trench 340, and surrounded by the isolation spacer 370. A bottom surface of the isolation spacer 370 is below a top surface of the N-type doped poly silicon layer 106. The common select line 372 can be poly silicon doped with N-type dopants such as, for example, phosphorus (P) and arsenic (As). The common select line 372 is grown from the N-type doped poly silicon layer 106, in which the N-type doped poly silicon layer 106 serves as a common source plane of the semiconductor structure 10. Then a metal plug 374 is formed connected to the common select line 372.

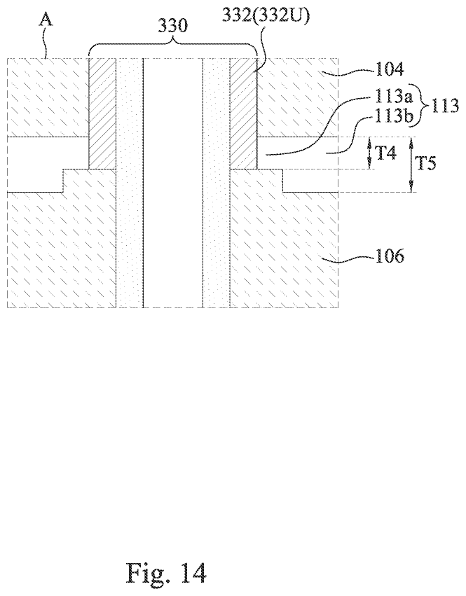

Reference is made to FIG. 14, which is a partial view of area A of the semiconductor structure 10 in FIG. 13. In some embodiments, the third oxide layer 113 has a first portion 113a surrounding the upper segment 332U of the vertical channel structures 330 and a second portion 113b connecting to the first portion 113a. The thickness T4 of the first portion 113a is smaller than the thickness T5 of the second portion 113b. The bottom surface of the first portion 113a of the third oxide layer 113 is substantially coplanar with the bottom surface of the upper segment 332U of the storage layer 332 of the vertical channel structure 330. In some embodiments, the bottom surface of the first portion 113a of the third oxide layer 113 and the bottom surface of the upper segment 332U of the storage layer 332 can be plane surfaces, convex surfaces, or concave surfaces.

Reference is made back to FIG. 13. The formation of the semiconductor structure 10 is completed, and the semiconductor structure 10 serves as a semiconductor device having memory cells. At least one of the gate structures 360 at bottom of the semiconductor structure 10 and the P-type doped fourth poly silicon layer 104 together serve as ground select lines (GSL) of the semiconductor structure 10. The N-type doped poly silicon layer 106 serves as a common source plane of the semiconductor structure 10. The distance between the N-type doped poly silicon layer 106 and the ground select lines (e.g. the P-type doped fourth poly silicon layer 104) is very short. In some embodiments, the distance between the N-type doped poly silicon layer 106 and the P-type doped fourth poly silicon layer 104 is the thickness T4 of the first portion 113a of the oxide layer 113, which is about 300 Å only, thus the thermal budget of diffusing the N-type dopant of the N-type doped poly silicon layer 106 is decreased. Furthermore, using the P-type doped fourth poly silicon layer 104 as the bottom conductive layer of the ground select lines, the erase speed of the memory cells of the present disclosure can be faster, and the current leakage (Ioff) can be reduced, comparing to a comparative example having no bottom conductive layer.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor device, comprising:
a peripheral circuit region comprising a plurality of complementary metal-oxide-semiconductor components;
a substrate on the peripheral circuit region comprising:
an N-type doped poly silicon layer on the peripheral circuit region;
an oxide layer on the N-type doped poly silicon layer; and
a P-type doped poly silicon layer on the oxide layer; and
an array region on the substrate comprising:
a plurality of gate structures and a plurality of insulating layers alternately stacked on the P-type doped poly silicon layer, wherein a bottommost gate structure of the gate structures and the P-type doped poly silicon layer together serve as a plurality ground select lines of the semiconductor device; and
a vertical channel structure penetrating the gate structures and the insulating layers and extending into the N-type doped poly silicon layer.

2. The semiconductor device of claim 1, wherein a thickness of the P-type doped poly silicon layer is greater than a thickness of each of the gate structures.

3. The semiconductor device of claim 1, wherein a ratio of a thickness of the P-type doped poly silicon layer to a thickness of each of the gate structures is about 3 to 4.

4. The semiconductor device of claim 1, wherein a thickness of the P-type doped poly silicon layer is smaller than a thickness of the N-type doped poly silicon layer.

5. The semiconductor device of claim 1, wherein a portion of a channel layer of the vertical channel structure is in contact with the N-type doped poly silicon layer.

6. The semiconductor device of claim 5, wherein a storage layer of the vertical channel structure comprises an upper segment surrounding a top of the channel layer and a lower segment surrounding a bottom of the channel layer, and the portion of the channel layer of the vertical channel structure is between the upper segment and the lower segment.

7. The semiconductor device of claim 6, wherein the oxide layer comprises a first portion surrounding the upper segment of the storage layer and a second portion connecting to the first portion, wherein a thickness of the first portion is smaller than a thickness of the second portion.

8. The semiconductor device of claim 7, wherein a bottom surface of the upper segment of the storage layer is substantially coplanar with a bottom surface of the first portion of the oxide layer.

9. The semiconductor device of claim 6, wherein a bottom surface of the upper segment of the storage layer is higher than a bottommost surface of the oxide layer.

10. The semiconductor device of claim 1, further comprising:
a common select line penetrating the array region and extending into the substrate; and
an isolation spacer surrounding the common select line.

11. The semiconductor device of claim 10, wherein a bottom surface of the isolation spacer is below a top surface of the N-type doped poly silicon layer.

12. A method of fabricating a semiconductor device, comprising:
providing a structure, the structure comprising:
a peripheral circuit region comprising a plurality of complementary metal-oxide-semiconductor components;
a substrate on the peripheral circuit region comprising:
a first poly silicon layer on the peripheral circuit region, wherein the first poly silicon layer is doped with N-type dopants;
a first oxide layer on the first poly silicon layer;
a second poly silicon layer on the first oxide layer;
a second oxide layer on the second poly silicon layer;
a third poly silicon layer on the second oxide layer;
a third oxide layer on the third poly silicon layer; and
a fourth poly silicon layer on the third oxide layer, wherein the fourth poly silicon layer is doped with P-type dopants; and
an array region on the substrate comprising:
a plurality of first insulating layers and a plurality of second insulating layers alternately stacked on the fourth poly silicon layer; and
a vertical channel structure penetrating the first insulating layers and the second insulating layers and extending into the first poly silicon layer;
removing the second poly silicon layer and removing the first oxide layer and the second oxide layer thereby forming a cavity between the third poly silicon layer and the first poly silicon layer; and
filling the cavity with an N-type doped poly silicon material, such that an N-type doped poly silicon layer is formed between the third oxide layer and the peripheral circuit region.

13. The method of claim 12, wherein the removing the second poly silicon layer comprises;
forming a trench in the structure to expose the second oxide layer;
forming a spacer on a sidewall of the trench;
deepening the trench to expose the second poly silicon layer; and
etching the second poly silicon layer.

14. The method of claim 13, wherein the removing the first oxide layer and the second oxide layer comprises:
removing a portion of a storage layer of the vertical channel structure and a portion of the spacer, such that the cavity is formed between the third poly silicon layer and the first poly silicon layer.

15. The method of claim 14, wherein the spacer comprises a first nitride layer on the sidewall of the trench, an oxide layer on the first nitride layer, and a second nitride layer on the oxide layer, and the removing the portion of the spacer comprises removing the second nitride layer and the oxide layer of the spacer.

16. The method of claim 14, wherein the storage layer of the vertical channel structure is recessed from the third oxide layer after the portion of the storage layer of the vertical channel structure is removed.

17. The method of claim 13, further comprising:
removing the spacer; and
forming an isolation spacer on the sidewall of the trench, a sidewall of the N-type doped poly silicon layer, and a sidewall of the fourth poly silicon layer.

18. The method of claim 17, further comprising:
epitaxially growing a common select line from the N-type doped poly silicon layer, wherein the common select line fills the trench and is surrounded by the isolation spacer.

19. The method of claim 12, further comprising:
replacing the second insulating layers with a plurality of gate structures.

20. The method of claim 19, further comprising:
performing an oxidation process on a sidewall of the fourth poly silicon layer and a sidewall of the N-type doped poly silicon layer before replacing the second insulating layers with a plurality of gate structures.
